(19) United States
(12) Patent Application Publication
(10) Pub. No.: US 2004/0095890 A1
(43) Pub. Date: May 20, 2004

(54) Traffic generating switch

(76) Inventors: Hain Chung Wang, Tu-Chen (TW); Xiao-Wen Sun, Tu-chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/335,297

(22) Filed: Dec. 30, 2002

(30) Foreign Application Priority Data
Nov. 15, 2002 (TW) 91133437

(51) Int. Cl. G01R 31/08

(52) U.S. Cl. 370/250

(57) ABSTRACT

A traffic generating switch (1) has alternative operating modes, namely switching mode and traffic generation mode. The switch includes software modules (10), hardware modules (20), a buffer (30), and a plurality of communication ports (40). The software modules include a switch control module (12), a traffic generator control module (14), and a common platform (16). The switch control module is capable of receiving and forwarding packets, and the traffic generator control module is capable of generating instructions for traffic generation. The hardware modules include a forwarding device (22), a traffic generation device (24), and a media access controlling device (26). When the switch works under traffic generation mode, the traffic generator control module generates instructions for traffic generation according to parameters set by users. Thereafter, the traffic generation device generates corresponding packets according to the instructions, and forwards the packets to relevant communication ports via the media access controlling device.

### BACKGROUND OF THE INVENTION

1. Field of the Invention

The present invention relates to electronic network apparatuses and switches, and particularly to a switch having alternative operating modes, namely switching mode and traffic generation mode.

2. Description of Related Art

A traffic generator is a device that can generate packets to emulate ordinary traffic load carried by a network device such as a switch or a router or by a network environment. This enables testing of the performance and of the accuracy of the target device or network environment. Testing of accuracy is known as a functional test. Conventionally, a traffic generator is implemented as a separate device from the system undergoing testing. In the case of testing a switch, the traffic generator is a tool dedicated to testing the target switch by artificially generating packets and feeding them to the target switch. The target switch is referred to as the device under test (DUT). In addition to generating inbound traffic to the DUT, the traffic generator may also observe and analyze outbound traffic from the DUT. For example, the traffic generator may examine the contents and record the volume of outbound traffic. As such, the traffic generator allows users to evaluate the performance of the DUT and validate its operability.

Known commercial traffic generators are machines built specifically for the above-mentioned purposes. A main focus of such traffic generators is capacity. That is, the capability of the traffic generator to generate traffic at full line rate under all conditions with a high port count. As a result, the cost of such traffic generators is usually high. A typical price is in the range from several tens of thousands of US dollars to hundreds of thousands of US dollars. In fact, in at least many cases where a switch is tested, only a traffic generator with a few ports running at a rate that is well under the full line rate is needed. This is particularly true for functional tests.

For the aforementioned reasons, there is a strong economic need to develop a low-cost traffic generator.

### SUMMARY OF THE INVENTION

It is a general object of the present invention to provide traffic generation functionality in a switch such as an Ethernet switch.

It is another object of the present invention to provide a switch that can alternatively perform switching and traffic generation.

To achieve the above objects, a switch according to the present invention has alternative operating modes, namely switching mode and traffic generation mode. The switch comprises software modules, hardware modules, a buffer, and a plurality of communication ports. The software modules comprise a switch control module, a traffic generator control module, and a common platform. The switch control module is capable of receiving and forwarding packets, and the traffic generator control module is capable of generating instructions for traffic generation. The hardware modules comprise a forwarding device, a traffic generation device, and a media access controlling device. The forwarding device receives packets from the switch control module, and forwards the packets to one or more network devices connected with one or more of the communication ports via the media access controlling device. The traffic generation device is capable of generating corresponding packets according to the instructions generated by the traffic generator control module, and forwards the packets to one or more relevant of the communication ports via the media access controlling device.

Other objects, advantages and novel features of the present invention will be drawn from the following detailed description of the present invention with the attached drawing, in which:

### BRIEF DESCRIPTION OF THE DRAWING

FIG. 1 is a block diagram of parts of a switch according to the present invention.

### DETAILED DESCRIPTION OF THE INVENTION

Reference will now be made to the drawing figures to describe the present invention in detail.

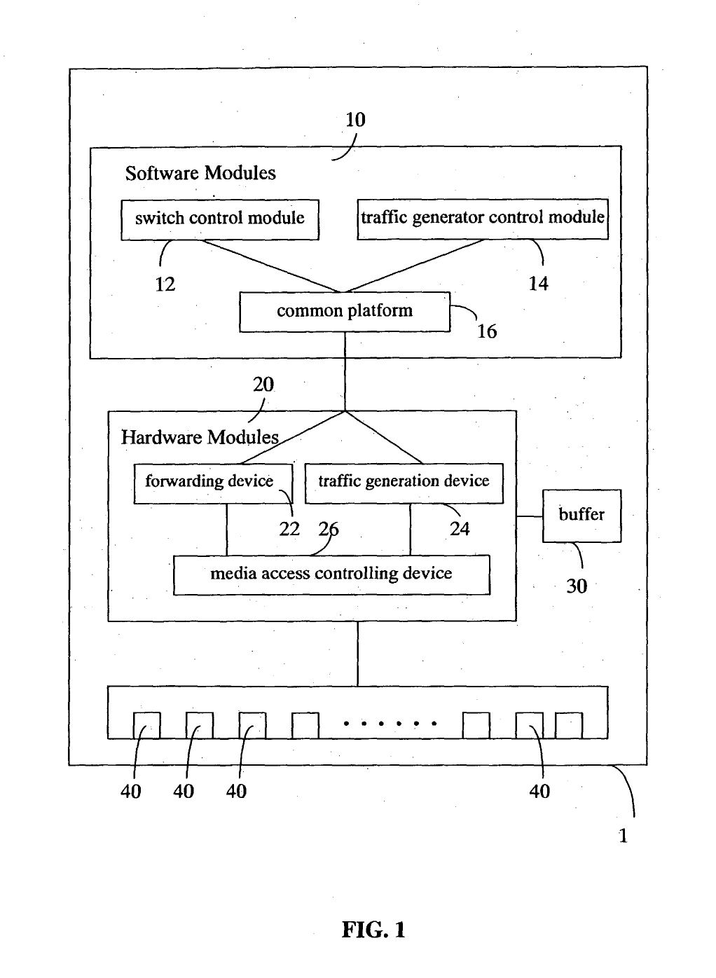

FIG. 1 is a block diagram of parts of a switch 1 according to the present invention. The switch 1 can operate under switching mode or traffic generation mode. The switch 1 comprises software modules 10, hardware modules 20, a buffer 30, and a plurality of communication ports 40.

The software modules 10 comprise a switch control module 12, a traffic generator control module 14, and a common platform 16. The switch control module 12 handles normal switching specific functions such as packet receiving and forwarding. The traffic generator control module 14 controls traffic generation. For example, traffic streams, traffic rate and distribution, packet content and length, and statistics maintenance. The common platform 16 is common software infrastructure that may be shared by the switch control module 12 and the traffic generator control module 14. Such infrastructure may, for example, be an operating system, a TCP/IP stack, a database, device drivers and various utilities.

The hardware modules 20 can be based on an ASIC (Application Specific Integrated Circuit), and comprise a forwarding device 22, a traffic generation device 24 and a media access controlling device 26. The forwarding device 22 is a packet forwarding module used in switching mode. The forwarding device 22 receives packets transmitted by the switch control module 12, and transmits the packets to relevant communication ports 40 via the media access controlling device 26. In this way, the switch 1 communicates with devices (not shown) connected with the relevant communication ports 40. The traffic generation device 24 is a hardware module in the ASIC used in traffic generation mode. The traffic generation device 24 generates packets each with a certain traffic rate, packet content and packet length according to instructions generated by the traffic generator control module 14. The packets are transmitted to relevant communication ports 40 via the media access controlling device 26, to test performance of devices (not shown). The buffer 30 is used respectively by the switch control module 12 and the traffic generation device 24 to save packets temporarily.

The communication ports 40 of the switch 1 can be communication ports of a conventional switch. Each communication port 40 can be connected with network devices such as a workstation, terminal devices, servers and routers (not shown). In this way, the switch 1 is able to communicate with other network devices.

During system initialization (i.e., boot-up), a user is prompted to specify the operating mode via a user interface (not shown). If no operating mode is specified, the default mode is switching mode. The operating mode can be changed via the user interface. When the switch 1 operates under switching mode, the switch 1 works as a normal switch. When the switch 1 operates under traffic generation mode, the switch 1 can be connected with a plurality of devices undergoing testing. Users can set different parameters (such as traffic rate, packet content and packet length) for the switch 1. The traffic generator control module 14 generates operation instructions according to the parameters set by users. Thereafter, the traffic generation device 24 generates corresponding traffic information according to the instructions, and transmits the traffic information to relevant communication ports via the media access controlling device 26 to test the performance of devices. The traffic generator control module 14 is able to maintain a variety of statistical information. For example, packet counts for transmission and receipt at each port 40, corrupted packets, lost packets, and average traffic rate. The statistical information is shown on the user interface.

Although the invention has been described in language specific to structural features and/or methodological steps, it is to be understood that the invention defined in the appended claims is not necessarily limited to the specific features or steps described. Rather, the specific features and steps are disclosed as preferred forms of implementing the claimed invention.

What is claimed is:

1. A switch having alternative operating modes being switching mode and traffic generation mode, the switch comprising software modules, hardware modules and a plurality of communication ports, wherein:
said software modules comprise a first module and a second module, said first module being capable of receiving and forwarding packets, and said second module being capable of generating instructions for traffic generation; and
said hardware modules comprising a first device, a second device and a media access controlling device, said first device receiving packets from said first module and forwarding the packets to one or more network devices connected with one or more of the communication ports via the media access controlling device, said second device being capable of generating corresponding packets according to the instructions generated by said second module and forwarding the packets to one or more relevant of the communication ports via the media access controlling device.

2. The switch as described in claim 1, wherein the software modules comprise a third module, said third module being a common software infrastructure shared by said first module and said second module.

3. The switch as described in claim 1, wherein the hardware modules are based on an application specific integrated circuit.

4. The switch as described in claim 1, wherein said second module is capable of receiving parameters for traffic generation set by a user via a user interface, and generating instructions for traffic generation.

5. The switch as described in claim 4, wherein said parameters comprise any one or more of traffic rate, packet content and packet length.

6. The switch as described in claim 1, wherein said second module is capable of traffic stream control, traffic rate and distribution control, packet content and length control, and statistics maintenance.

7. A hybrid switch/traffic generator device in communication with other network devices, comprising:
a software modules including first and second modules under a condition that said first module is capable of receiving and forwarding packets and said second module is capable of generating instructions for traffic generation; and
a hardware modules including first and second devices under a condition that said first device receives and forwards said packets and said second device generates corresponding packets according the instructions; wherein
said software modules and said hardware modules share a same platform.

8. A hybrid switch/traffic generator device in communication with other network devices, comprising:
a software modules including first and second modules under a condition that said first module is capable of receiving and forwarding packets and said second module is capable of generating instructions for traffic generation; and
a hardware modules including first and second devices under a condition that said first device receives and forwards said packets and said second device generates corresponding packets according the instructions; wherein
both said first device and said second device are connected to a same media access controlling device which communicates with said other network devices via a same group of communication ports.
